(19) United States
(12) Patent Application Publication
(10) Pub. No.: US 2003/0052648 A1
(43) Pub. Date: Mar. 20, 2003

(54) Remote commander battery low voltage alert system

(75) Inventors: Hiroshi Hara, San Diego, CA (US); Toshikazu Ido, San Diego, CA (US)

Correspondence Address: Rogitz & Associates, 750 B Street, Suite 3120, San Diego, CA, 92101, US

(73) Assignee: SONY CORPORATION, Tokyo (JP)

(21) Appl. No.: 10/164,852

(22) Filed: Jun. 6, 2002

Related U.S. Application Data
(60) Provisional application No. 60/323,761, filed on Sep. 17, 2001.

(51) Int. Cl. H02J 7/00

(52) U.S. Cl. 320/132

(57) ABSTRACT

An apparatus and method for battery level detection of a remote control device including a voltage detection device coupled to a battery for generating a reset signal upon detecting a low voltage condition. A microprocessor is coupled to the voltage detection device, the microprocessor generating an output signal upon receiving a reset signal and a key signal. A display which is not coupled to the remote control device for receiving the output signal and indicating the low voltage condition. Further, a software algorithm is provided to calculate and analyze the voltage hysteresis of the battery to detect the low voltage condition of the battery.

### COPYRIGHT NOTICE

A portion of the disclosure of this patent document contains material which is subject to copyright protection. The copyright owner has no objection to the facsimile reproduction of the patent document or the patent disclosure, as it appears in the Patent and Trademark Office patent file or records, but otherwise reserves all copyright rights whatsoever.

I. Field of the Invention

This invention relates generally to an apparatus for detecting the battery voltage of a remote control device, and more particularly when the battery voltage decreases below a reference voltage, the remote control device sends an alert to another device, which informs the user that the battery voltage in the remote control device is low.

II. Background of the Invention

In recent years there has been an increased number of remote control devices driven by batteries. This tendency is seen in conjunction with numerous devices such as televisions, office machines, and many other types of equipment that require portable remote control devices that have batteries. The battery voltage in these remote control devices can sometimes be lowered so as to cause the remote control device not to perform normal operations. In these events, sometimes the user may not be aware of the low voltage of the battery and surmise that the remote control device itself is not performing well or that a device being controlled by the remote control device needs fixing.

Hence, coping with the battery level in a remote control device can be a source of frustration for the user. In order for the user to avoid this problem, they can either always keep new batteries in the device, or periodically remove the batteries of the remote control device and test their voltage level. Moreover, should a user use a remote control device more often, the battery fatigue may be more extensive than that resulting from normal use requiring more removal and testing of the batteries.

Devices for monitoring the battery level, and operating on battery power, may include a battery monitoring circuit, which notifies the user when the battery output voltage falls below a low battery set point voltage, and may also put the device in a suspended mode when the battery output voltage falls below this set point voltage.

A problem with the present monitoring devices is that in a remote control device, such as a remote commander for a television set, the user does not know how much operating time remains. For example, if the user is operating a remote commander and does not have a spare battery, he/she may want to perform certain procedures such as keying the television channel selector keys that require operation time before returning to a facility where a replacement battery is available. Moreover, the user may surmise that there is another problem with the remote commander which is not with it's battery, but a defect in the remote commander or defects associated with the television set's operation.

### SUMMARY OF THE INVENTION

It is an object of the present invention to provide a battery level monitoring system to monitor the battery level in a remote control device by using a display of a device controlled by the remote control device.

One embodiment of the present invention is a battery level detection device for a remote control device including a voltage detection device coupled to a battery for generating a reset signal upon detecting a low voltage condition. A microprocessor is coupled to the voltage detection device, the microprocessor generating an output signal upon receiving a reset signal and a key signal. A display is not coupled to the remote control device for receiving the output signal and indicating the low voltage condition. Further, a software algorithm is provided to calculate and analyze the voltage hysteresis of the battery to detect the low voltage condition of the battery.

Another embodiment of the present invention is a device for monitoring a battery voltage level, the device including a monitoring circuit for monitoring a battery voltage level and generating a reset signal; a controller coupled to the monitoring circuit for receiving the reset signal; key switches coupled to the controller for generating a detect key signal; wherein when the battery voltage level decreases below a threshold level, the monitoring circuit sends the reset signal to the controller which in turn waits for the detect key signal and upon receiving the detect key signal sends an alert signal to a detached device.

In yet another embodiment of the present invention is a method for battery level detection for a remote control device, including: coupling a voltage detection device to a battery; and coupling a microprocessor to the voltage detection device wherein when the microprocessor detects a signal of a voltage less than a threshold amount by the voltage detection device, the microprocessor waits for another signal whereupon receiving the another signal generates an output signal.

The features of the invention believed to be novel are set forth with particularity in the appended claims. The invention itself however, both as to organization and method of operation, together with further objects and advantages thereof, may be best understood by reference to the following description taken in conjunction with the accompanying drawing.

### BRIEF DESCRIPTION OF THE DRAWINGS

The following detailed description, given by way of example, and not intended to limit the present invention solely thereto, will best be understood in conjunction with the accompanying drawings in which:

FIG. 1 is a flow chart of the battery detection device and display according to an embodiment of the present invention.

FIGS. 2a and 2b are block diagrams of a simplified circuit diagram of the battery detection device according to an embodiment of the present invention.

FIG. 3 is a flow chart of the two step battery detection operation according to an embodiment of the present invention.

### DETAILED DESCRIPTION OF THE INVENTION

In the present invention, the remote control device has the capability to detect the voltage level of the battery. A microprocessor inside the remote control device has a software algorithm that can calculate and analyze the hysteresis of the battery voltage. When the algorithm detects a typical hysteresis of a low voltage, in essence the end of the battery cycle, it prepares a dedicated code to be issued. When the user operates the remote control device to issue a command, the dedicated code indicating the low voltage can be issued before any other codes are issued. Finally, the display device will receive the dedicated code and display on the screen a message or an icon alerting the user about the low voltage of the battery. Accordingly, the user can then replace the battery with a new battery..

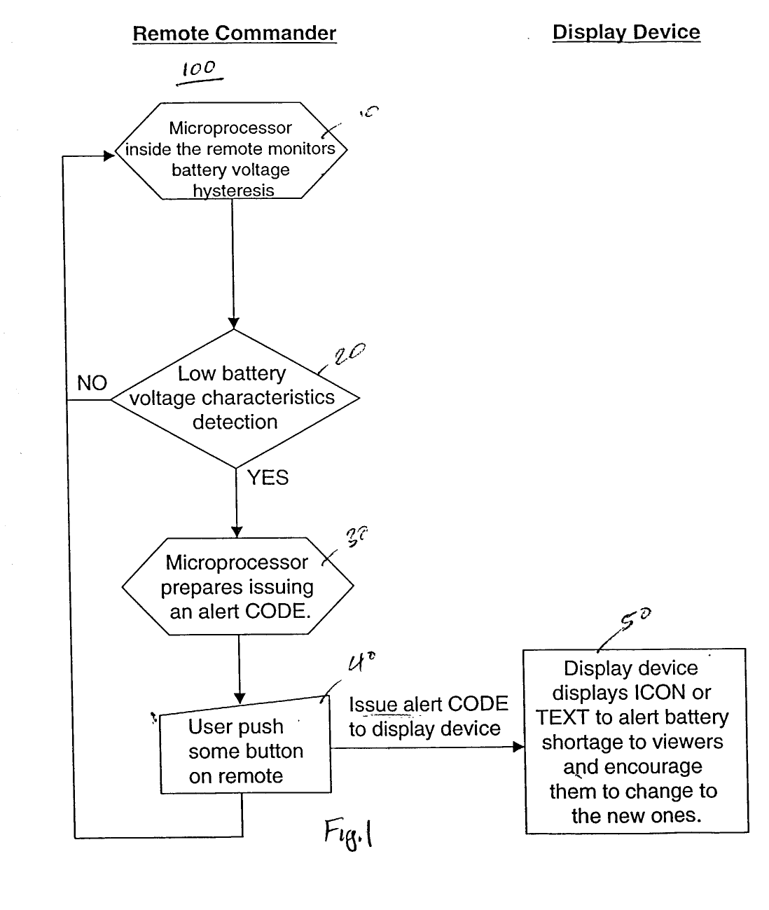

Turning now to FIG. 1, displayed is a flow diagram 100 of a low battery voltage monitoring process for a remote control device used with a television set. The low battery voltage monitoring process includes a microprocessor inside the remote control device which monitors at step 10 the battery voltage hysteresis, at step 20 detects a low battery voltage characteristic, which enables a determination as to whether there is a low battery voltage. If not, the microprocessor continues to monitor the battery voltage at step 10 and again another low battery detection characteristic at step 20 is performed. If it is determined that there is a low battery characteristic, then the microprocessor issues an alert code at step 30. Upon the user pressing any of the keys, for example, keys 1 through 9 or the channel up/down or volume high/low keys at step 40, the microprocessor issues an alert code which causes an icon or text message to be displayed on the device being controlled. The display device being controlled displays the low battery message at step 50 in the form of an icon and/or text to indicate to the user that the battery level in the remote control device is low, thus prompting the user to change the batteries, reduce usage of the remote control device, or at the very least make them aware that batteries are at the end of their useful life.

FIGS. 2a and 2b are block diagrams of a remote control device's microprocessor controlled voltage detection system. FIG. 2a discloses a battery detection circuit 200 of a battery 245, reset IC 220 connected across the battery leads for generating a reset signal upon detecting a low voltage condition, a microprocessor 210, key pad switches 240 and an LED emitter 230. The LED emitter 230 sends a signal to a detached display 245 indicating a low voltage condition. The display 245 can be found on a computer, video player, video cassette recorder, projection device and the like. FIG. 2b is similar to FIG. 2a including the battery 260, key switches 300, LED emitter 290, and display 310 except the reset circuit 280 is incorporated into the microprocessor 270.

By way of operation, the remote control device's microprocessor controlled voltage detection system of the present invention includes a microprocessor 210 for receiving the reset signals. The reference voltage of a threshold voltage comparator like device included in the reset IC 220 is set to equal the appropriate low voltage level for the particular battery being used. The microprocessor monitors the output from the reset IC 220, in a sampling interval of, for example, one millisecond. When the reset IC sends a reset signal, this would for example if a comparator therein is switched, when a low battery condition is detected, the reset IC 220 will signal low battery to the user regardless of the considerations.

Next, the terminal voltage samples taken by the microprocessor are processed (see step 10 of FIG. 1) to calculate the internal battery resistance and its derivative rate of change over a period of hours. When the algorithm included in the microprocessor detects the typical hysteresis of the low battery condition the alert code is prepared to be issued to the display before other codes are to be used by the remote control device. Alternately, if either the terminal resistance or its derivative exceeds preprogrammed limits, a low battery signal is sent to the display thus alerting the user.

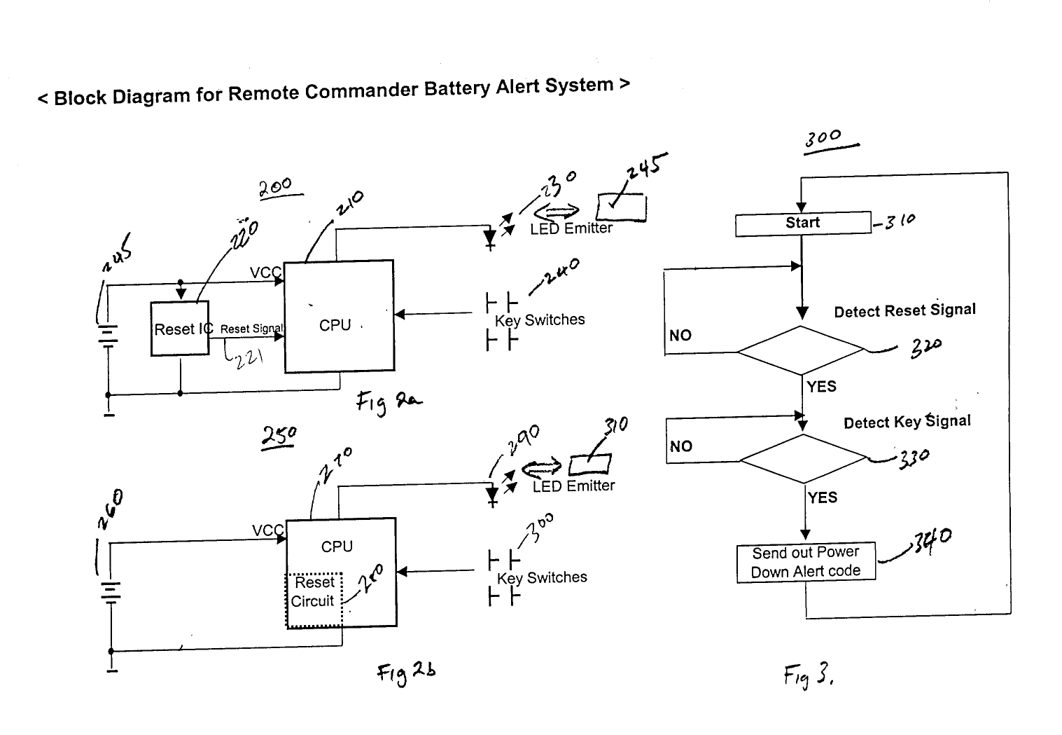

FIG. 3 is a flow diagram 300 showing the two step operation for the microprocessor control of, initially detecting the detect reset signal 320 from the reset circuit, if such a detect signal is detected then proceeding to detect a key pad signal 330 actuated by the key pad switches. Upon detecting of the key signal 330, sends an out power down alert code 340 to the display device.

The low battery detection circuit comprises a microprocessor that samples battery terminal voltage under light and heavy loads, and indicates a low battery condition when either the voltage rate of change with respect to the time and to the sample voltage, or to the rate of change of the internal resistance with respect to time of the battery has exceeded a predetermined limit. The battery detection circuit for indicating the low battery condition is comprises a detection circuit for determining the sample voltage and for indicating a low battery condition when a hysteresis of the battery voltage falls below certain predetermined thresholds. The voltage comparator has an input threshold voltage that establishes the lowest acceptable battery voltage condition and the circuit includes apparatus for indicating the condition has been traversed upon sampling of the terminal voltage.

Thus it is apparent that in accordance with the present invention, an apparatus that fully satisfies the objectives, aims and advantages is set forth above. While the invention has been described in conjunction with specific embodiments, it is evident that many alternatives, modifications, permutations and variations will become apparent to those skilled in the art in light of the foregoing description. Accordingly, it is intended that the present invention embrace all such alternatives, modifications and variations as fall within the scope of the appended claims.

We claim:

1. A battery level detection device for a remote control device, comprising:
a voltage detection device coupled to a battery for generating a reset signal upon detecting a low voltage condition;
a microprocessor coupled to the voltage detection device, said microprocessor generating an output signal upon receiving said reset signal and a key signal; and
a display not coupled to the remote control device for receiving the output signal and indicating the low voltage condition.

2. The battery level detection device of claim 1, wherein said key signal being generated by a key stroke of a key located on the remote control device.

3. The battery level detection device of claim 1, comprising:
an LED emitter receiving the output signal generated by the microprocessor and sending said output signal to the display.

4. The battery level detection device of claim 1, comprising:
a voltage detection device including a reset circuit for generating a reset signal to the microprocessor device so as to detect the low voltage condition.

5. A device for monitoring a battery voltage level, said device comprising:
a monitoring circuit for monitoring a battery voltage level and generating a reset signal;
a controller coupled to the monitoring circuit for receiving the reset signal;
key switches coupled to said controller for generating a detect key signal; wherein when the battery voltage level decreases below a threshold level, the monitoring circuit sends the reset signal to the controller which in turn waits for said detect key signal and upon receiving said detect key signal sends an alert signal to a detached device.

6. The device of claim 5, wherein said key switches includes being switches on the remote control device.

7. The device of claim 6, wherein the monitoring circuit being incorporated in the controller.

8. The device of claim 7, wherein said detached device is selected from a television, a computer device, a digital video player, a video cassette recorder, and a projection device.

9. A method for battery level detection for a remote control device, comprising:
coupling a voltage detection device to a battery; and
coupling a microprocessor to the voltage detection device wherein when the microprocessor detects a signal of a voltage less than a threshold amount by said voltage detection device, said microprocessor waits for another signal whereupon receiving said another signal generates an output signal.

10. The method of claim 9, wherein the another signal being generated by a key stroke of a number of keys located on the remote control device.

11. The method of claim 9, comprising:
coupling an LED emitter to the microprocessor for receiving the output signal.

12. The method of claim 9, wherein the LED emitter generating a signal to a controlled device wherein said controlled device selected from a television, a computer device, a digital video player, a video cassette recorder, or a projection device.

13. A device for monitoring a battery voltage level, said device comprising:
a monitoring means for monitoring a battery voltage level and generating a reset signal;
a controller means coupled to the monitoring means for receiving the reset signal;
key switch means coupled to said controller means for generating a detect key signal;
wherein when the battery voltage level decreases below a threshold level, the monitoring means sends the reset signal to the controller means which in turn waits for said detect key signal and upon receiving said detect key signal sends an alert signal to a detached means.

14. The device of claim 13, wherein said detached means selected from a television, a computer device, a digital video player, a video cassette recorder, and a projection device.
